(19) United States
(12) Patent Application Publication
(10) Pub. No.: US 2006/0262050 A1
(43) Pub. Date: Nov. 23, 2006

(54) Electroluminescent display device and data line drive circuit

(75) Inventors: Takashi Ogawa, Gifu (JP); Shoichiro Matsumoto, Ogaki-shi (JP); Kyoji Ikeda, Gifu (JP)

Correspondence Address: MORRISON & FOERSTER LLP, 1650 TYSONS BOULEVARD, SUITE 300, MCLEAN, VA, 22102, US

(73) Assignee: SANYO ELECTRIC CO., LTD., Osaka (JP)

(21) Appl. No.: 11/413,126

(22) Filed: Apr. 28, 2006

(30) Foreign Application Priority Data
Apr. 28, 2005 (JP) 2005-131261
Apr. 28, 2005 (JP) 2005-131262
Apr. 28, 2005 (JP) 2005-131263

(51) Int. Cl. G09G 3/30

(52) U.S. Cl. 345/76

(57) ABSTRACT

A high quality display is realized with an organic EL display device by reducing a coarse look and variations in brightness on a display panel due to variations in threshold voltages of driver transistors. Also, a cost of the display device is reduced by eliminating a need for an external driver IC. The electroluminescent display device of this invention is of passive drive type that has no TFT in each pixel or of semi-passive drive type that has a pixel selection transistor and an organic EL device in each pixel. With this, an aperture ratio of the pixel is improved and the high quality display is realized by reducing the coarse look. Various kinds of drive circuits such as a horizontal shift register, a data line drive circuit and a vertical shift register are formed on a single glass substrate together with a pixel region in which the electroluminescent device is formed. The data line drive circuit has a first data line drive circuit and a second data line drive circuit. The first data line drive circuit provides data lines with drive currents corresponding to a display signal and has a threshold voltage compensation circuit that compensates for a threshold voltage of the driver transistor. The second data line drive circuit is structured similarly. However, while the first data line drive circuit is controlled by a vertical clock, the second data line drive circuit is controlled by a reverse vertical clock. The first data line drive circuit and the second data line drive circuit output the drive current to the data line alternately for every other one horizontal period.

### CROSS-REFERENCE OF THE INVENTION

This application is based on Japanese Patent Application Nos. 2005-131261, 2005-131262 and 2005-131263, the content of which is incorporated herein by reference in its entirety.

### BACKGROUND OF THE INVENTION

1. Field of the Invention

This invention relates to an electroluminescent display device, each pixel of which is provided with an electroluminescent device, and a data line drive circuit that provides the electroluminescent device with a drive current.

2. Description of the Related Art

Organic EL display devices using organic electroluminescent devices (hereafter referred to as organic EL devices) have been developed in recent years as display devices to replace CRT and LCD. An emphasis is laid on development of an active drive type organic EL display panel, each pixel of which is provided with a pixel selection TFT (Thin Film Transistor) and a driver TFT that drives the organic EL device.

On the other hand, an electronic view finder (hereafter referred to as EVF) using the organic EL display device has been also developed. The EVF is attached as a finder to a body of a camera such as a digital camera. It enables magnifying an image of an object displayed on the organic EL display panel by five to ten times with an optical lens.

Further description on the technologies mentioned above is provided in Japanese Patent Application Publication No. 2002-175035.

However, the EVF using the active drive type organic EL display panel has a problem that it gives a grainy look to a light-emitting portion on the display panel, since the pixel selection TFTs, driver TFTs, gate signal lines and drain signal lines included in the active drive type organic EL display panel reduce an aperture ratio, a ratio of an area of open portions (light-emitting portions) to an area of the pixels on the display panel, and make non-open portions at borders between the pixels visible as a grating pattern when the display panel is magnified with the optical lens.

It has another problem that even slight variations in threshold voltages of the driver TFTs in the pixels cause variations in electric currents flowing through the EL devices and cause variations in brightness of the light emitted from the pixels to give a coarse look to the display, since a very little current flowing through the EL device disposed in each of the very small pixels of the EVF can be easily affected by the variations in the threshold voltages.

Therefore, it is conceived to improve the aperture ratio of the pixels using a passive drive type organic EL display device that has no TFTs in its pixels. In this case, the organic EL devices are provided with drive currents corresponding to display data from a data line drive circuit through data lines.

However, there is a problem that variations in threshold voltages of driver transistors integrated in the active drive type display device cause variations in the drive currents and resultant variations in the brightness on the display panel.

### SUMMARY OF THE INVENTION

This invention provides an electroluminescent display device having a plurality of data lines, a plurality of cathode lines isolated from each other and disposed to intersect the data lines, a plurality of electroluminescent devices each disposed around an intersection of each of the data lines and each of the cathode lines, a horizontal shift register that sequentially samples externally provided display signals, a data line drive circuit that reads-in and retains the display signals sampled by the horizontal shift register and collectively provides the plurality of data lines with drive currents corresponding to the display signals for a predetermined period and a vertical shift register that sequentially selects a cathode line out of the plurality of cathode lines and set an electric potential of the selected cathode line to form a current path through which a current driving the electroluminescent device flows, wherein the plurality of electroluminescent devices, the horizontal shift register, the data line drive circuit and the vertical shift register are formed on a single substrate.

This invention also provides an electroluminescent display device having a plurality of data lines, a plurality of gate lines disposed to intersect the plurality of data lines, a plurality of pixels each disposed around an intersection of each of the data lines and each of the gate lines and including a pixel selection transistor with a gate connected to one of the gate lines and a drain connected to one of the data lines and an electroluminescent device connected to the pixel selection transistor, a horizontal shift register that sequentially samples externally provided display signals, a data line drive circuit that reads-in and retains the display signals sampled by the horizontal shift register and collectively provides the plurality of data lines with drive currents corresponding to the display signals for a predetermined period and a vertical shift register that provides the plurality of gate lines with vertical scanning signals, wherein the plurality of pixels, the horizontal shift register, the data line drive circuit and the vertical shift register are formed on a single substrate.

This invention further offers a data line drive circuit that provides an electroluminescent device with a drive current, the data line drive circuit having a first data line drive circuit that outputs a first drive current to a data line during a first period and a second drive circuit that outputs a second drive current to the data line during a second period, the first and the second currents corresponding to a display data and being compensated for a threshold voltage of a driver transistor.

### BRIEF DESCRIPTION OF THE DRAWINGS

FIG. 1 is an equivalent circuit diagram of an organic EL display device according to a first embodiment of this invention.

FIG. 2 is a timing chart showing horizontal scanning in the organic EL display device according to the first embodiment and in an organic EL display device according to a second embodiment of this invention.

FIGS. 3A and 3B show cross-sectional structures of the organic EL display device according to the first embodiment of this invention.

FIG. 4 is a timing chart showing vertical scanning in the organic EL display device according to the first embodiment of this invention.

FIG. 5 is a circuit diagram of a first data line drive circuit DLD1 in the organic EL display devices according to the first and the second embodiments of this invention.

FIG. 6 is a circuit diagram of a second data line drive circuit DLD2 in the organic EL display devices according to the first and the second embodiments of this invention.

FIG. 7 is a timing chart showing operation of the first data line drive circuit DLD1 and the second data line drive circuit DLD2 in the organic EL display devices according to the first and the second embodiments of this invention.

FIG. 8 is an equivalent circuit diagram of the organic EL display device according to the second embodiment of this invention.

FIG. 9 shows a cross-sectional structure of the organic EL display device according to the second embodiment of this invention.

FIG. 10 is a timing chart showing vertical scanning in the organic EL display device according to the second embodiment of this invention.

### DETAILED DESCRIPTION OF THE INVENTION

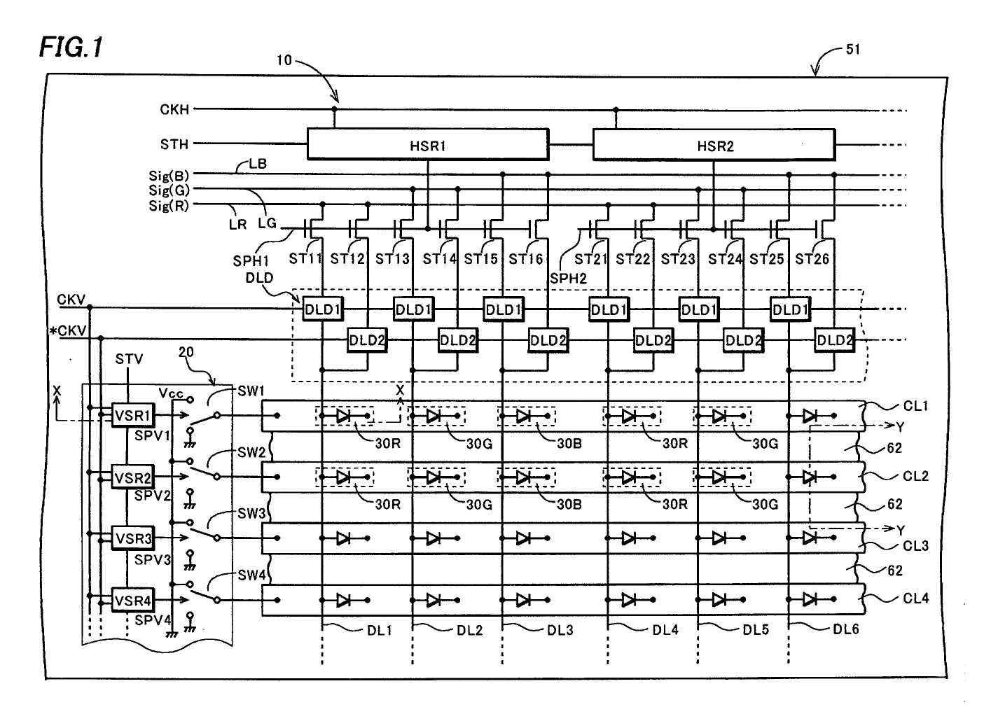

Next, an organic EL display device according to a first embodiment of this invention will be described hereafter, referring to the drawings. FIG. 1 is an equivalent circuit diagram of the organic EL display device.

First, a structure of a pixel region of the organic EL display device will be described. A plurality of data lines DL1-DL6 extends in a vertical direction (top to bottom direction in FIG. 1) on a glass substrate 51. A plurality of cathode lines CL1-CL4 extends in a horizontal direction (left to right direction in FIG. 1) that is perpendicular to the data lines DL1-DL6. A pixel including an organic EL device is disposed around an intersection of each of the data lines and each of the cathode lines. The number of data lines and the number of cathode lines may be chosen arbitrarily.

An organic EL device 30R that emits red light is disposed around each of four intersections of the first column data line DL1 and the cathode lines CL1-CL4. Anodes of the organic EL devices 30R that emit red light are connected to the data line DL1, while each of their cathodes is connected to corresponding each of the cathode lines CL1-CL4. Similarly, an organic EL device 30G that emits green light is disposed around each of four intersections of the second column data line DL2 and the cathode lines CL1-CL4. Anodes of the organic EL devices 30G that emit green light are connected to the data line DL2, while each of their cathodes is connected to corresponding each of the cathode lines CL1-CL4.

Similarly, an organic EL device 30B that emits blue light is disposed around each of four intersections of the third column data line DL3 and the cathode lines CL1-CL4. Anodes of the organic EL devices 30B that emit blue light are connected to the data line DL3, while each of their cathodes is connected to corresponding each of the cathode lines CL1-CL4. Pixels in a fourth column and beyond are structured in a way to repeat the structure described above. Inorganic EL devices may be used instead of the organic EL devices 30R, 30G and 30B.

Next, structures of a horizontal shift register 10 and a data line drive circuit DLD will be described hereafter. The horizontal shift register 10 and the data line drive circuit DLD are formed on the glass substrate 51. The horizontal shift register 10 has a plurality of horizontal shift register units HSR1, HSR2, and so on and a plurality of sampling transistors ST11, ST12, and so on. The sampling transistors ST11, ST12, and so on are thin film transistors.

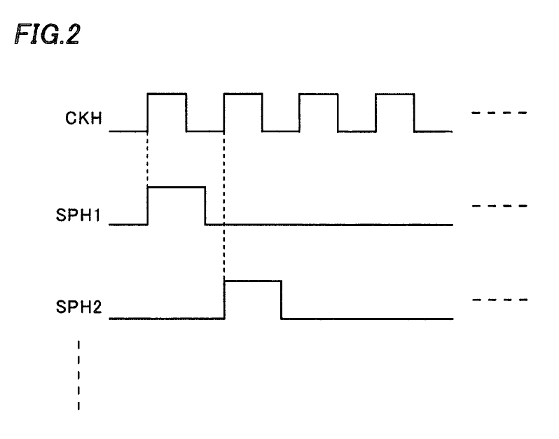

Each of the plurality of horizontal shift register units HSR1, HSR2, and so on sequentially outputs each of horizontal scanning pulses SPH1, SPH2, and so on, respectively, by shifting a horizontal start pulse STH in synchronization with a horizontal clock CKH, as shown in FIG. 2.

Six of the sampling transistors ST11, ST12, ST13, ST14, ST15 and ST16 are disposed corresponding to the horizontal shift register unit HSR1 in a first stage. The horizontal scanning pulse SPH1 is inputted in common to gates of the six sampling transistors ST11, ST12, ST13, ST14, ST15 and ST16. Similarly, six of the sampling transistors ST21, ST22, ST23, ST24, ST25 and ST26 are disposed corresponding to the horizontal shift register unit HSR2 in a second stage. The horizontal scanning pulse SPH2 is inputted in common to gates of the six sampling transistors ST21, ST22, ST23, ST24, ST25 and ST26.

Regarding the six sampling transistors ST11, ST12, ST13, ST14, ST15 and ST16, sources of a first couple of the sampling transistors ST11 and ST12 are connected to a first display signal line LR that supplies a red display signal Sig(R), sources of a second couple of the sampling transistors ST13 and ST14 are connected to a second display signal line LG that supplies a green display signal Sig(G) and sources of a third couple of the sampling transistors ST15 and ST16 are connected to a third display signal line LB that supplies a blue display signal Sig(B).

The data line drive circuit DLD has a first data line drive circuit DLD1 and a second data line drive circuit DLD2 corresponding to each of the data lines DL1-DL6. For example, the first data line drive circuit DLD1 corresponding to the data line DL1 reads-in and retains the red display signal Sig(R) through the sampling transistor ST11, and provides the data line DL1 with a drive current corresponding to the red display signal Sig(R). The first data line drive circuit DLD1 has a threshold voltage compensation circuit that compensates for a threshold voltage of a driver transistor, as will be described later. The variations in the brightness on the display panel due to the variations in the threshold voltages of the driver transistors can be suppressed because the drive current independent of the threshold voltage of the driver transistor is obtained with the threshold voltage compensation circuit.

The second data line drive circuit DLD2 operates similarly. While the first data line drive circuit DLD1 is controlled by a vertical clock CKV that has a period of two horizontal periods, the second data line drive circuit is controlled by a reverse vertical clock *CKV that is a reverse of the vertical clock CKV. As a result, the first data line drive circuit DLD1 and the second data line drive circuit DLD2 output the drive current to the data line DL1 alternately for every other one horizontal period (1H period). One horizontal period means a time required to scan one horizontal line (the cathode line CL1, for example).

Another first data line drive circuit DLD1 and another second data line drive circuit DLD2 corresponding to each of the other data lines DL2-DL6 are structured similarly.

Next, a structure of a vertical shift register 20 will be described hereafter. The vertical shift register 20 has a plurality of vertical shift register units VSR1, VSR2, and so on, connected in series and switching devices SW1, SW2, SW3 and SW4 disposed on the glass substrate 51. The vertical shift register 20 is formed of thin film transistors. The switching devices SW1, SW2, SW3 and SW4 may be formed of inverters using thin film transistors.

Each of the plurality of vertical shift register units VSR1, VSR2, and so on sequentially outputs each of vertical scanning pulses SPV1, SPV2, and so on, respectively, by shifting a vertical start pulse STV in synchronization with the vertical clock CKV and the reverse vertical clock *CVK. Each of the switching devices SW1, SW2, SW3 and SW4 switches according to each of the vertical scanning pulses SPV1, SPV2, SPV3 and SPV4, respectively, and sets an electric potential of each of the cathode lines CL1-CL4 at a ground electric potential GND or at a power supply electric potential Vcc. That is, each of the switching devices SW1, SW2, SW3 and SW4 sets the electric potential of each of the cathode lines CL1-CL4 at the ground electric potential GND to form current paths for the organic EL devices in the pixels only when each of the vertical scanning pulses SPV1, SPV2, SPV3 and SPV4 is at a high level, respectively.

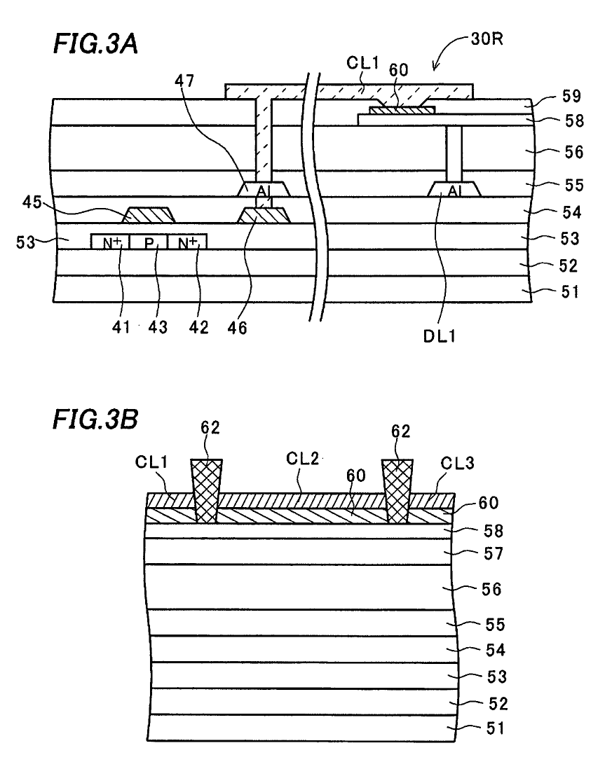

FIGS. 3A and 3B show schematic cross-sectional structures of the above-mentioned organic EL display device. FIG. 3A is a cross-sectional view of a section X-X in FIG. 1, while FIG. 3B is a cross-sectional view of a section Y-Y in FIG. 1.

FIG. 3A shows the vertical shift register unit VSR1 in the left side and the organic EL device 30R in the pixel region in the right side. An insulation film 52 made of a SiO₂ film and a SiNₓ film is formed on the glass substrate 51. A polysilicon layer that makes an active layer of a thin film transistor in the shift register unit VSR1 is formed on the insulation film 52. An N⁺-type drain layer 41 and an N⁺-type source layer 42 are formed in the polysilicon layer, and a P-type channel region 43 is formed between them. A gate insulation film 53 made of a SiO₂ film and a SiNₓ film is formed on the polysilicon layer. A gate electrode 45 made of chromium is formed above the channel region 43 through the gate insulation film 53.

An interlayer insulation film 54 is formed on the gate electrode 45. In a region where the shift register unit VSR1 is formed, an aluminum electrode 47 is formed on the interlayer insulation film 54, making a contact with an underlying chromium electrode 46.

In the pixel region, the data line DL1 made of aluminum is formed on the interlayer insulation film 54. A protection film 55 and a first planarizing insulation film 56 are formed on the aluminum electrode 47 and the data line DL1. An anode 58 made of ITO (Indium Tin Oxide) is formed on the first planarizing insulation film 56 in the pixel region. An organic EL layer 60 is formed on the anode 58, and a second planarizing insulation film 59 is formed to cover a part of the organic EL layer 60. The cathode line CL1 is formed on the organic EL layer 60. The cathode line CL1 extends over to the region where the vertical shift register unit VSR1 is formed, and is connected to the aluminum electrode 47 through a contact hole.

FIG. 3B shows cross-sectional structure of the cathode lines CL1, CL2 and CL3 in the pixel region. Cathode line isolation materials 62 made of photoresist material are formed between the cathode lines CL1 and CL2 and between the cathode lines CL2 and CL3 to separate cathode lines adjacent to each other physically as well as electrically.

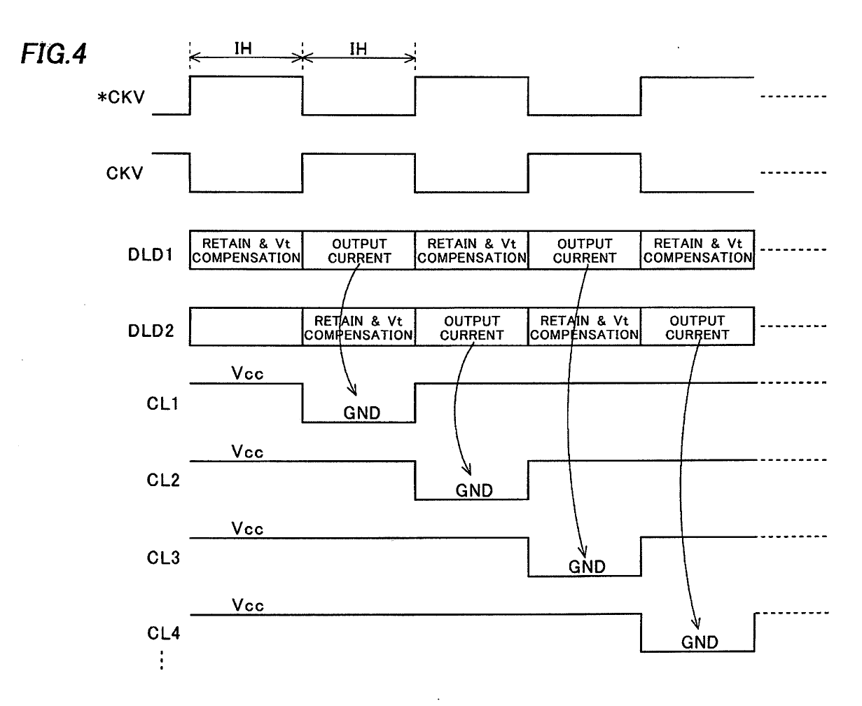

Next, operation of the organic EL display device described above will be explained hereinafter, referring to a timing chart shown in FIG. 4. During a first one horizontal period (1H period), the display signals Sig(R), Sig(G) and Sig(B) sampled by the sampling transistors ST11, ST13, ST15, and so on are sequentially read into the plurality of first data line drive circuits DLD1 and compensated for the threshold voltages of the driver transistors while they are retained.

During a second 1H period, the plurality of first data line drive circuits DLD1 outputs drive currents compensated for the threshold voltage to the data lines DL 1-DL6 all together. Only the cathode line CL 1 drops to the ground electric potential GND during the second 1H period. As a result, the drive currents flow through the organic EL devices 30R, 30G and 30B in the first row connected to the cathode line CL1, and each of the organic EL devices 30R, 30G and 30B emits light to a brightness corresponding to each of the drive currents, respectively. That is, regarding the organic EL device 30R, for example, the drive current supplied to the data line DL1 flows into the cathode line CL1 through the organic EL device 30R.

On the other hand, in the second 1H period, during which the plurality of first data line drive circuits DLD1 outputs the drive currents, the display signals Sig(R), Sig(G) and Sig(B) sampled by the plurality of sampling transistors ST12, ST14, ST16, and so on are sequentially read into the plurality of second data line drive circuits DLD2 and compensated for the threshold voltages of the driver transistors while they are retained.

During a third 1H period, the plurality of second data line driver circuits DLD2 outputs drive currents compensated for the threshold voltages to the data lines DL1-DL6 all together. Only the cathode line CL2 drops to the ground electric potential GND during the third 1H period, and the drive currents flow through the organic EL devices 30R, 30G and 30B in the second row connected to the cathode line CL2, and each of the organic EL devices 30R, 30G and 30B emits light to a brightness corresponding to each of the drive currents, respectively.

On the other hand, in the third 1H period, during which the plurality of second data line drive circuits DLD2 outputs the drive currents, the display signals Sig(R), Sig(G) and Sig(B) sampled by the plurality of sampling transistors ST11, ST13, ST15, and so on are sequentially read into the plurality of first data line drive circuits DLD1 and compensated for the threshold voltages of the driver transistors while they are retained.

A frame of image is displayed by repeating the operation described above over one frame period. The organic EL display device according to the first embodiment is a passive drive type that does not have a TFT in the pixel as described above. As a result, the aperture ratio of the pixel is improved and the coarse look on the display is reduced to realize a high quality display. And because various kinds of drive circuits such as the horizontal shift register 10, the data line drive circuit DLD and the vertical shift register 20 are formed on the single glass substrate 51 together with the pixel region in which the organic EL devices 30R, 30G and 30B are formed, there is no need to attach an external driver IC, making it possible to reduce the cost.

Also, because the first embodiment adopts a line-sequential drive method by which the data line drive circuit DLD provides the data lines DL1-DL6 with the drive currents all together for one horizontal period, a light-emitting period of the organic EL devices 30R, 30G and 30B can be made longer compared with an ordinary passive drive type display device, making it possible to realize a relatively bright display panel.

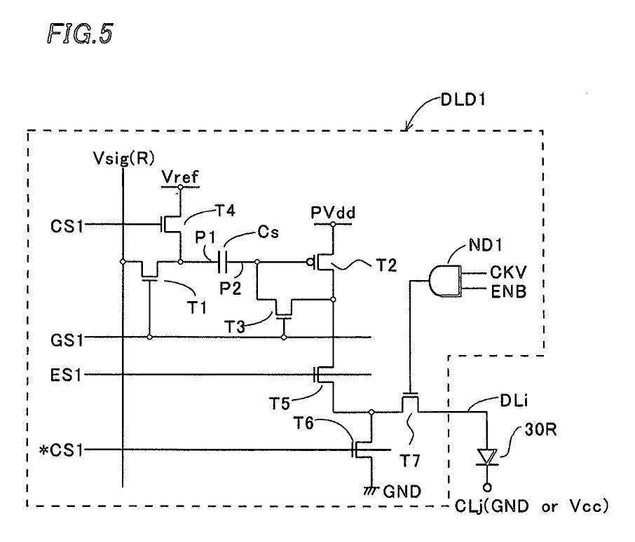

Next, detailed structures and operation of the first data line drive circuit DLD1 and the second data line drive circuit DLD2 will be described, referring to FIGS. 5, 6 and 7. The first data line drive circuit DLD1 is made of a first through seventh thin film transistors T1-T7, a coupling capacitor Cs and a first NAND circuit ND1, as shown in FIG. 5. The first thin film transistor T1 and the third through seventh thin film transistors T3-T7 are of N-channel type, while the second thin film transistor T2 is of P-channel type.

The first thin film transistor T1 is for reading-in of the display signal, with its source connected to the sampling transistor, and a first control signal GS1 is applied to its gate. The first thin film transistor T1 is turned on when the first control signal GS1 is at a high level to read-in the display signal Sig(R), for example, and applies the display signal Sig(R) to a first terminal P1 of the coupling capacitor Cs, which is connected to a drain of the first thin film transistor T1. A second terminal P2 of the coupling capacitor Cs, which is facing to the first terminal P1, is connected to a gate of the second thin film transistor T2. The second thin film transistor T2 is a driver transistor, and the power supply electric potential PVdd is applied to its source.

And the first control signal GS1 is applied to a gate of the third thin film transistor T3 that is connected between the gate and the drain of the second thin film transistor T2. The third thin film transistor T3 is turned on to short-circuit the gate and the drain of the second thin film transistor when the first control signal GS1 is at the high level.

A second control signal CS1 is applied to a gate of the fourth thin film transistor T4, a reference electric potential Vref is applied to its source and its drain is connected to the first terminal P1 of the coupling capacitor Cs. The fourth thin film transistor T4 is turned on to set the first terminal P1 of the coupling capacitor Cs at the reference electric potential Vref when the second control signal CS1 is at the high level.

The fifth thin film transistor T5 and the sixth thin film transistor T6 are connected in series between the second thin film transistor T2 and the ground. A third control signal ES1 is applied to a gate of the fifth thin film transistor T5, and a reverse signal *CS1 that is a reverse of the second control signal CS1 is applied to a gate of the sixth thin film transistor T6.

The fifth thin film transistor T5 is connected to the data line DLi through the seventh thin film transistor T7 that is to control outputting of the drive current. An output of the first NAND circuit ND1 is applied to a gate of the seventh thin film transistor T7. The vertical clock CKV and an output enable signal ENB are inputted to the first NAND circuit ND1. The output enable signal ENB is a signal to prevent overlapping between the output signal of the first NAND circuit ND1 and an output signal of a second NAND circuit ND2 in the second data line drive circuit DLD2, which will be described later. And the organic EL device 30R, for example, is connected with the data line DLi, as described above.

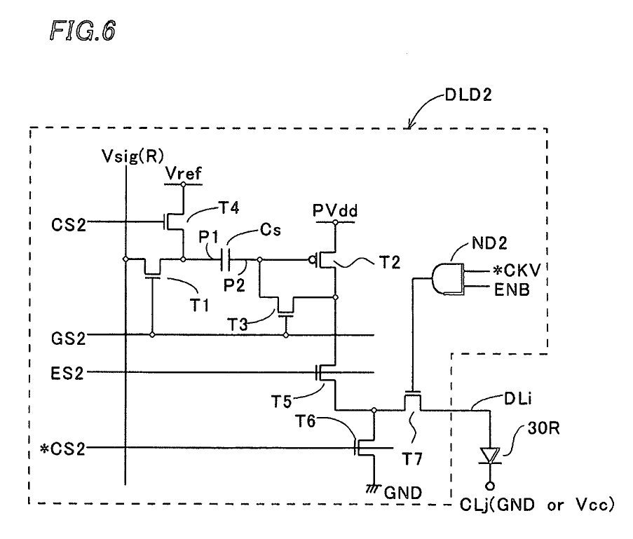

Like the first data line drive circuit DLD1, the second data line drive circuit DLD2 is made of a first through seventh thin film transistors T1-T7, a coupling capacitor Cs and the second NAND circuit ND2, as shown in FIG. 6. A fourth control signal GS2 is applied to gates of the first and the third thin film transistors T1 and T3. A fifth control signal CS2 is applied to a gate of the fourth thin film transistor T4. A sixth control signal ES2 is applied to a gate of the fifth thin film transistor T5. Each of the fourth, fifth and sixth control signals GS2, CS2 and ES2 is shifted by 1H period from each of the first, second and third control signals GS1, CS1 and ES1, respectively.

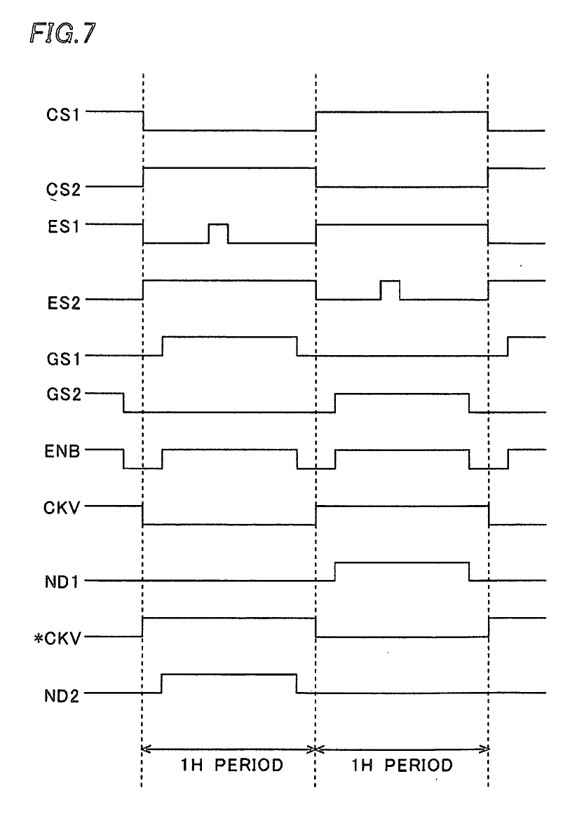

Operation of the first data line drive circuit DLD1 and the second data line drive circuit DLD2 will be explained, referring to FIG. 7. First, during the first 1H period, the first data line drive circuit DLD1 reads-in the display signal Sig and compensates for the threshold voltage of the second thin film transistor T2 that is the driver transistor. During the first 1H period, on the other hand, the second data line drive circuit DLD2 outputs the compensated drive current to the data line DLi.

Detailed explanation on the operation of the first data line drive circuit DLD1 is as follows.

First, when the first control signal GS1 turns to the high level, the first thin film transistor T1 is turned on to apply the display signal Sig(R), for example, from the sampling transistor to the first terminal P1 of the coupling capacitor Cs through the first thin film transistor T1. Also, the third thin film transistor T3 is turned on to short-circuit the gate and the drain of the second thin film transistor T2. Next, when the third control signal ES1 turns to the high level, electric charges at the gate of the second thin film transistor T2 are discharged to the ground through the fifth thin film transistor T5 and the sixth thin film transistor T6.

After that, the fifth thin film transistor T5 is turned off when the third control signal ES1 turns to a low level. Since the gate and the drain of the second thin film transistor T2 become electrically floating as a result, an electric potential at the gate and the drain becomes PVdd−Vtp. Vtp is an absolute value of the threshold voltage of the second thin film transistor T2. Then, the first thin film transistor T1 and the third thin film transistor T3 are turned off when the first control signal GS1 turns to the low level.

After that, when the second control signal CS1 turns to the high level in the second 1H period, the fourth thin film transistor T4 is turned on to set an electric potential at the first terminal P1 of the coupling capacitor Cs at the reference electric potential Vref. And the sixth thin film transistor T6 is turned off.

Since the electric potential at the first terminal P1 of the coupling capacitor Cs changes from Vsig to Vref when the fourth thin film transistor T4 is turned on, an electric potential at the second terminal P2 of the coupling capacitor Cs, that is the electric potential Vg at the gate of the second thin film transistor T2, changes from PVdd−Vtp to PVdd−Vtp+Vref−Vsig consequently.

After that, the fifth thin film transistor T5 is turned on when the third control signal ES1 turns to the high level again and the seventh thin film transistor T7 is turned on when an output of the first NAND circuit ND1 rises to a high level. Thus the second thin film transistor T2 is connected to the data line DLi through the fifth thin film transistor T5 and the seventh thin film transistor T7.

The drive current I flowing through the second thin film transistor T2 is represented by the following equation:
I=1/2·β·(Vgs+Vtp)²
where β is a constant.
Since,
Vgs=Vg−PVdd=−Vtp+Vref−Vsig
It follows:
I=1/2·β·(Vref−Vsig)²

That is, the drive current I is made to be independent of the threshold voltage Vtp of the second thin film transistor T2. The drive current I is supplied to the organic EL device 30R through the data line DLi to make a display corresponding to the display signal Vsig(R).

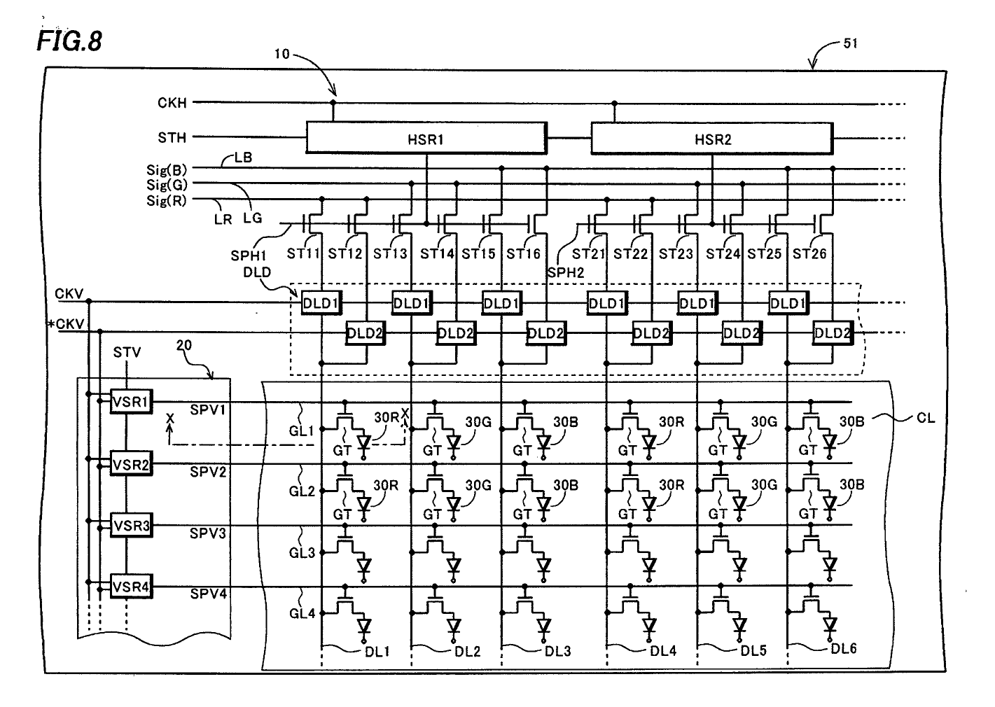

Next, an organic EL display device according to a second embodiment of this invention will be described hereafter, referring to the drawings. FIG. 8 is an equivalent circuit diagram of the organic EL display device.

First, a structure of a pixel region of the organic EL display device will be described. A plurality of data lines DL1-DL6 extends in a vertical direction (top to bottom direction in FIG. 8) on a glass substrate 51. A plurality of gate lines GL1-GL4 extends in a horizontal direction (left to right direction in FIG. 8) that is perpendicular to the data lines DL1-DL6. Each pixel including a pixel selection transistor GT and an organic EL device is disposed around an intersection of each of the data lines and each of the gate lines. The number of data lines and the number of gate lines may be chosen arbitrarily.

A pixel selection transistor GT and an organic EL device 30R that emits red light are disposed around each of four intersections of the first column data line DL1 and the gate lines GL1-GL4. A drain of the pixel selection transistor GT is connected to the data line DL1 and its source is connected to an anode of the organic EL device 30R that emits red light. And a cathode of the organic EL device 30R is connected to a common cathode layer CL formed all over the pixel region.

Similarly, a pixel selection transistor GT and an organic EL device 30G that emits green light are disposed around each of four intersections of the second column data line DL2 and the gate lines GL1-GL4. A drain of the pixel selection transistor GT is connected to the data line DL2 and its source is connected to an anode of the organic EL device 30G that emits green light. And a cathode of the organic EL device 30G is connected to the common cathode layer CL.

Similarly, a pixel selection transistor GT and an organic EL device 30B that emits blue light are disposed around each of four intersections of the third column data line DL3 and the gate lines GL1-GL4. A drain of the pixel selection transistor GT is connected to the data line DL3 and its source is connected to an anode of the organic EL device 30B that emits blue light. And a cathode of the organic EL device 30B is connected to the common cathode layer CL. Pixels in a fourth column and beyond are structured in a way to repeat the structure described above. Inorganic EL devices may be used instead of the organic EL devices 30R, 30G and 30B.

Next, structures of a horizontal shift register 10 and a data line drive circuit DLD will be described hereafter. The horizontal shift register 10 and the data line drive circuit DLD are formed on the glass substrate 51. The horizontal shift register 10 has a plurality of horizontal shift register units HSR1, HSR2, and so on and a plurality of sampling transistors ST11, ST12, and so on. The sampling transistors ST11, ST12, and so on are thin film transistors.

Each of the plurality of horizontal shift register units HSR1, HSR2, and so on sequentially outputs each of horizontal scanning pulses SPH1, SPH2, and so on, respectively, by shifting a horizontal start pulse STH in synchronization with a horizontal clock CKH, as shown in FIG. 2.

Six of the sampling transistors ST11, ST12, ST13, ST14, ST15 and ST16 are disposed corresponding to the horizontal shift register unit HSR1 in a first stage. The horizontal scanning pulse SPH1 is inputted in common to gates of the six sampling transistors ST11, ST12, ST13, ST14, ST15 and ST16. Similarly, six of the sampling transistors ST21, ST22, ST23, ST24, ST25 and ST26 are disposed corresponding to the horizontal shift register unit HSR2 in a second stage. The horizontal scanning pulse SPH2 is inputted in common to gates of the six sampling transistors ST21, ST22, ST23, ST24, ST25 and ST26.

Regarding the six sampling transistors ST11, ST12, ST13, ST14, ST15 and ST16, sources of a first couple of the sampling transistors ST11 and ST12 are connected to a first display signal line LR that supplies a red display signal Sig(R), sources of a second couple of the sampling transistors ST13 and ST14 are connected to a second display signal line LG that supplies a green display signal Sig(G) and sources of a third couple of the sampling transistors ST15 and ST16 are connected to a third display signal line LB that supplies a blue display signal Sig(B).

The data line drive circuit DLD has a first data line drive circuit DLD1 and a second data line drive circuit DLD2 corresponding to each of the data lines DL1-DL6. For example, the first data line drive circuit DLD1 corresponding to the data line DL1 reads-in and retains the red display signal Sig(R) through the sampling transistor ST11, and provides the data line DL1 with a drive current corresponding to the red display signal Sig(R). The first data line drive circuit DLD1 has a threshold voltage compensation circuit that compensates for a threshold voltage of a driver transistor, as will be described later. The variations in the brightness on the display panel due to the variations in the threshold voltages of the driver transistors can be suppressed because the drive current independent of the threshold voltage of the driver transistor is obtained with the threshold voltage compensation circuit.

The second data line drive circuit DLD2 operates similarly. While the first data line drive circuit DLD1 is controlled by a vertical clock CKV that has a period of two horizontal periods, the second data line drive circuit is controlled by a reverse vertical clock *CKV that is a reverse of the vertical clock CKV. As a result, the first data line drive circuit DLD1 and the second data line drive circuit DLD2 output the drive current to the data line DL 1 alternately for every other one horizontal period (1H period). One horizontal period means a time required to scan one horizontal line (the gate line GL1, for example).

Another first data line drive circuit DLD1 and another second data line drive circuit DLD2 corresponding to each of the other data lines DL2-DL6 are structured similarly.

Next, a structure of a vertical shift register 20 will be described hereafter. The vertical shift register 20 has a plurality of vertical shift register units VSR1, VSR2, and so on, connected in series and disposed on the glass substrate 51. The vertical shift register 20 is formed of thin film transistors.

Each of the plurality of vertical shift register units VSR1, VSR2, and so on sequentially outputs each of vertical scanning pulses SPV1, SPV2, and so on to corresponding each of the gate lines GL1, GL2, GL3 and GL4, respectively, by shifting a vertical start pulse STV in synchronization with the vertical clock CKV and the reverse vertical clock *CVK. The pixel selection transistor GT connected to each of the gate lines GL1, GL2, GL3 and GL4 is turned on only for a period during which the corresponding each of the vertical scanning pulse SPV1, SPV2, SPV3 and SPV4 is at a high level.

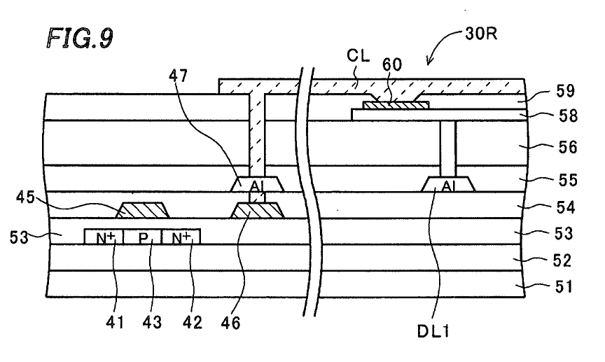

FIG. 9 shows a cross-sectional structure of the organic EL display device described above, and corresponds to a cross-sectional view of a section X-X in FIG. 8. An insulation film 52 made of a SiO₂ film and a SiNₓ film is formed on the glass substrate 51. A polysilicon layer that makes an active layer of a thin film transistor in the shift register unit VSR1 is formed on the insulation film 52. An N⁺-type drain layer 41 and an N⁺-type source layer 42 are formed in the polysilicon layer, and a P-type channel region 43 is formed between them. A gate insulation film 53 made of a SiO₂ film and a SiNₓ film is formed on the polysilicon layer. A gate electrode 45 made of chromium is formed above the channel region 43 through the gate insulation film 53.

An interlayer insulation film 54 is formed on the gate electrode 45. In a region where the shift register unit VSR1 is formed, an aluminum electrode 47 is formed on the interlayer insulation film 54, making a contact with an underlying chromium electrode 46.

In the pixel region, the data line DL1 made of aluminum is formed on the interlayer insulation film 54. A protection film 55 and a first planarizing insulation film 56 are formed on the aluminum electrode 47 and the data line DL1. An anode 58 made of ITO (Indium Tin Oxide) is formed on the first planarizing insulation film 56 in the pixel region. An organic EL layer 60 is formed on the anode 58, and a second planarizing insulation film 59 is formed to cover a part of the organic EL layer 60. The cathode layer CL is formed on the organic EL layer 60. The cathode layer CL extends over the region where the vertical shift register unit VSR1 is formed, and is connected to the aluminum electrode 47 through a contact hole.

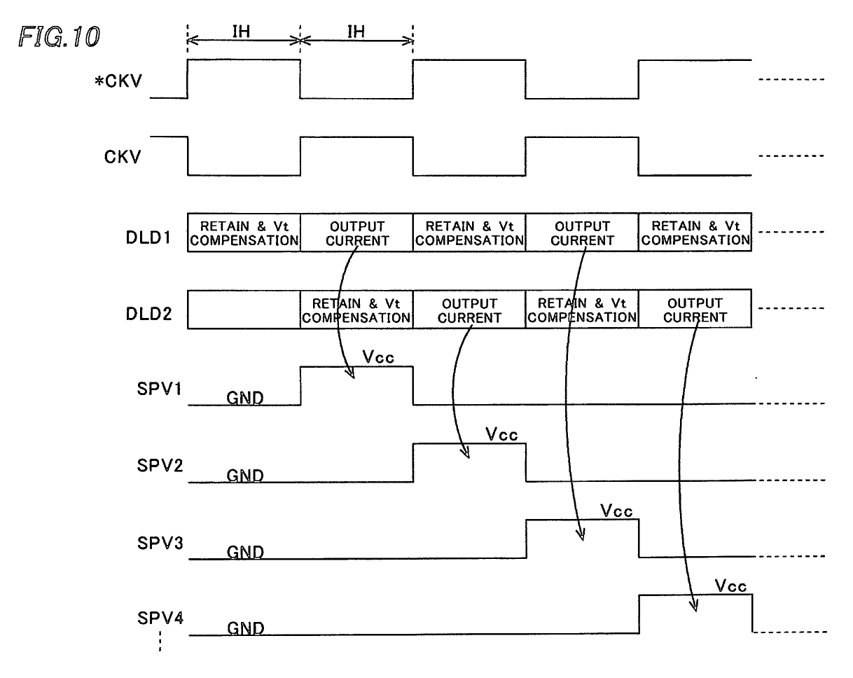

Next, operation of the organic EL display device described above will be explained hereinafter, referring to a timing chart shown in FIG. 10. During a first one horizontal period (1H period), the display signals Sig(R), Sig(G) and Sig(B) sampled by the sampling transistors ST11, ST13, ST15, and so on are sequentially read into the plurality of first data line drive circuits DLD1 and compensated for the threshold voltages of the driver transistors while they are retained.

During a second 1H period, the plurality of first data line drive circuits DLD1 outputs drive currents compensated for the threshold voltage to the data lines DL1-DL6 all together. During the second one horizontal period, the vertical scanning pulse SPV1 outputted to the gate line GL1 rises from a ground electric potential GND to a power supply electric potential Vcc. As a result, the pixel selection transistors GT connected to the first row gate line GL1 are turned on to provide the organic EL devices 30R, 30G and 30B connected to the first row gate line GL1 with the drive currents, and each of the organic EL devices 30R, 30G and 30B emits light to a brightness corresponding to each of the drive currents, respectively. That is, regarding the organic EL device 30R, the drive current supplied to the data line DL1 flows into the cathode layer CL through the pixel selection transistor GT and the organic EL device 30R to drive the organic EL device 30R to emit light to the brightness corresponding to the drive current.

On the other hand, in the second 1H period, during which the plurality of first data line drive circuits DLD1 outputs the drive currents, the display signals Sig(R), Sig(G) and Sig(B) sampled by the plurality of sampling transistors ST12, ST14, ST16, and so on are sequentially read into the plurality of second data line drive circuits DLD2 and compensated for the threshold voltages of the driver transistors while they are retained.

During a third 1H period, the plurality of second data line driver circuits DLD2 outputs drive currents compensated for the threshold voltages to the data lines DL1-DL6 all together. During the third 1H period, the vertical scanning pulse SPV2 outputted to the gate line GL2 rises from the ground electric potential GND to the power supply electric potential Vcc. As a result, the pixel selection transistors GT connected to the second row gate line GL2 are turned on to provide the organic EL devices 30R, 30G and 30B connected to the second row gate line GL2 with the drive currents, and each of the organic EL devices 30R, 30G and 30B emits light to a brightness corresponding to each of the drive currents, respectively. That is, regarding the organic EL device 30R, the drive current supplied to the data line DL1 flows into the cathode layer CL through the pixel selection transistor GT and the organic EL device 30R to drive the organic EL device 30R to emit light to the brightness corresponding to the drive current.

On the other hand, in the third 1H period, during which the plurality of second data line drive circuits DLD2 outputs the drive currents, the display signals Sig(R), Sig(G) and Sig(B) sampled by the plurality of sampling transistors ST11, ST13, ST15, and so on are sequentially read into the plurality of first data line drive circuits DLD1 and compensated for the threshold voltages of the driver transistors while they are retained.

A frame of image is displayed by repeating the operation described above over one frame period. Because the organic EL display device according to the second embodiment is a semi-passive drive type that has the electroluminescent device 30R, 30G or 30B and the pixel selection transistor GT in the pixel, the aperture ratio of the pixel is improved and a high quality display is realized by reducing the coarse look on the display. And because various kinds of drive circuits such as the horizontal shift register 10, the data line drive circuit DLD and the vertical shift register 20 are formed on the single glass substrate 51 together with the pixel region in which the organic EL devices 30R, 30G and 30B are formed, there is no need to attach an external driver IC, making it possible to reduce the cost. Also, because the second embodiment adopts a line-sequential drive method by which the data line drive circuit DLD provides the data lines DL1-DL6 with the drive currents all together for one horizontal period, a light-emitting period of the organic EL devices 30R, 30G and 30B can be made longer compared with an ordinary passive drive type display device, making it possible to realize a relatively bright display panel.

Next, detailed structures and operation of the first data line drive circuit DLD1 and the second data line drive circuit DLD2 will be described, referring to FIGS. 5, 6 and 7. The first data line drive circuit DLD1 is made of a first through seventh thin film transistors T1-T7, a coupling capacitor Cs and a first NAND circuit ND1, as shown in FIG. 5. The first thin film transistor T1 and the third through seventh thin film transistors T3-T7 are of N-channel type, while the second thin film transistor T2 is of P-channel type.

The first thin film transistor T1 is for reading-in of the display signal, with its source connected to the sampling transistor, and a first control signal GS1 is applied to its gate. The first thin film transistor T1 is turned on when the first control signal GS1 is at a high level to read-in the display signal Sig(R), for example, and applies the display signal Sig(R) to a first terminal P1 of the coupling capacitor Cs, which is connected to a drain of the first thin film transistor T1. A second terminal P2 of the coupling capacitor Cs, which is facing to the first terminal P1, is connected to a gate of the second thin film transistor T2. The second thin film transistor T2 is a driver transistor, and the power supply electric potential PVdd is applied to its source.

And the first control signal GS1 is applied to a gate of the third thin film transistor T3 that is connected between the gate and the drain of the second thin film transistor T2. The third thin film transistor T3 is turned on to short-circuit the gate and the drain of the second thin film transistor when the first control signal GS1 is at the high level.

A second control signal CS1 is applied to a gate of the fourth thin film transistor T4, a reference electric potential Vref is applied to its source and its drain is connected to the first terminal P1 of the coupling capacitor Cs. The fourth thin film transistor T4 is turned on to set the first terminal P1 of the coupling capacitor Cs at the reference electric potential Vref when the second control signal CS1 is at the high level.

The fifth thin film transistor T5 and the sixth thin film transistor T6 are connected in series between the second thin film transistor T2 and the ground. A third control signal ES1 is applied to a gate of the fifth thin film transistor T5, and a reverse signal *CS1 that is a reverse of the second control signal CS1 is applied to a gate of the sixth thin film transistor T6.

The fifth thin film transistor T5 is connected to the data line DLi through the seventh thin film transistor T7 that is to control outputting of the drive current. An output of the first NAND circuit ND1 is applied to a gate of the seventh thin film transistor T7. The vertical clock CKV and an output enable signal ENB are inputted to the first NAND circuit ND1. The output enable signal ENB is a signal to prevent overlapping between the output signal of the first NAND circuit ND1 and an output signal of a second NAND circuit ND2 in the second data line drive circuit DLD2, which will be described later. And the organic EL device 30R, for example, is connected with the data line DLi, as described above.

Like the first data line drive circuit DLD1, the second data line drive circuit DLD2 is made of a first through seventh thin film transistors T1-T7, a coupling capacitor Cs and the second NAND circuit ND2, as shown in FIG. 6. A fourth control signal GS2 is applied to gates of the first and the third thin film transistors T1 and T3. A fifth control signal CS2 is applied to a gate of the fourth thin film transistor T4. A sixth control signal ES2 is applied to a gate of the fifth thin film transistor T5. Each of the fourth, fifth and sixth control signals GS2, CS2 and ES2 is shifted by 1H period from each of the first, second and third control signals GS1, CS1 and ES1, respectively.

Operation of the first data line drive circuit DLD1 and the second data line drive circuit DLD2 will be explained, referring to FIG. 7. First, during the first 1H period, the first data line drive circuit DLD1 reads-in the display signal Sig and compensates for the threshold voltage of the second thin film transistor T2 that is the driver transistor. During the first 1H period, on the other hand, the second data line drive circuit DLD2 outputs the compensated drive current to the data line DLi.

Detailed explanation on the operation of the first data line drive circuit DLD1 is as follows.

First, when the first control signal GS1 turns to the high level, the first thin film transistor T1 is turned on to apply the display signal Sig(R), for example, from the sampling transistor to the first terminal P1 of the coupling capacitor Cs through the first thin film transistor T1. Also, the third thin film transistor T3 is turned on to short-circuit the gate and the drain of the second thin film transistor T2. Next, when the third control signal ES1 turns to the high level, electric charges at the gate of the second thin film transistor T2 are discharged to the ground through the fifth thin film transistor T5 and the sixth thin film transistor T6.

After that, the fifth thin film transistor T5 is turned off when the third control signal ES1 turns to a low level. Since the gate and the drain of the second thin film transistor T2 become electrically floating as a result, an electric potential at the gate and the drain becomes PVdd−Vtp. Vtp is an absolute value of the threshold voltage of the second thin film transistor T2. Then, the first thin film transistor T1 and the third thin film transistor T3 are turned off when the first control signal GS1 turns to the low level.

After that, when the second control signal CS1 turns to the high level in the second 1H period, the fourth thin film transistor T4 is turned on to set an electric potential at the first terminal P1 of the coupling capacitor Cs at the reference electric potential Vref. And the sixth thin film transistor T6 is turned off.

Since the electric potential at the first terminal P1 of the coupling capacitor Cs changes from Vsig to Vref when the fourth thin film transistor T4 is turned on, an electric potential at the second terminal P2 of the coupling capacitor Cs, that is the electric potential Vg at the gate of the second thin film transistor T2, changes from PVdd−Vtp to PVdd−Vtp+Vref−Vsig consequently.

After that, the fifth thin film transistor T5 is turned on when the third control signal ES1 turns to the high level again and the seventh thin film transistor T7 is turned on when an output of the first NAND circuit ND1 rises to a high level. Thus the second thin film transistor T2 is connected to the data line DLi through the fifth thin film transistor T5 and the seventh thin film transistor T7.

The drive current I flowing through the second thin film transistor T2 is represented by the following equation:
I=1/2·β·(Vgs+Vtp)²
where β is a constant.
Since,
Vgs=Vg−PVdd=−Vtp+Vref−Vsig
It follows:
I=1/2·β·(Vref−Vsig)²

That is, the drive current I is made to be independent of the threshold voltage Vtp of the second thin film transistor T2. The drive current I is supplied to the organic EL device 30R through the data line DLi to make a display corresponding to the display signal Vsig(R).

The electroluminescent display device according to the first embodiment of this invention is of the passive drive type that does not have a TFT in each of the pixels as described above. As a result, a high quality display is realized by reducing the grainy look and the coarse look on the display compared with the conventional active drive type EL display device.

That is, since being of the passive drive type allows practically using drain wirings both for providing image signals and for supplying the drive currents as well as sharing the pixel selection TFTs and the driver TFTs, and eliminates gate lines and capacitor lines to provide storage capacitors to retain the gate electric potentials of the driver TFTs, the aperture ratio can be improved and consequently the visibility of the grating pattern at the borders between the pixels can be reduced to reduce the grainy look on the display panel.

In addition, since the electroluminescent display device according to the first embodiment is of the passive drive type and uses the line-sequential drive, the signals for each row are provided all together and the signals are provided in common to the columns by the switch provided to each column to reduce variations in the brightness among the rows. The variations in the brightness among the columns are reduced by the compensation for the threshold voltages of the driver TFTs in the data line drive circuit that controls the amount of the electric current provided line-sequentially. The effects of suppressing the variations in the brightness among rows and columns result in the suppression of variations in the brightness of all the pixels over the panel to enable reducing the coarse look on the display panel.

Because various kinds of drive circuits such as the horizontal shift register, the data line drive circuit and the vertical shift register are formed on the single glass substrate together with the pixel region in which the electroluminescent devices are formed, there is no need to attach the external driver IC, making it possible to reduce the cost.

Also, because the electroluminescent display device according to the first embodiment adopts the line-sequential drive method used in an LCD and the like, in which the data line drive circuit provides the data lines with the drive currents all together for a predetermined period (one horizontal period, for example), the light-emitting period is made longer and thus a brighter display panel is made available compared with a conventional passive drive type display device that uses a dot-sequential drive method.

The electroluminescent display device according to the first embodiment is suitable for a small display device such as a display device for the EVF, because it is basically of passive drive type and the light-emitting period of the electroluminescent devices is shorter than that of the active drive type.

The electroluminescent display device according to the second embodiment of this invention is of the semi-passive drive type that has an electroluminescent device and a pixel selection transistor in each of the pixels. As a result, a high quality display is realized by reducing the grainy look and the coarse look on the display compared with the conventional active drive type EL display device.

That is, since being of the semi-passive drive type allows practically using the drain wirings both for providing image signals and for supplying the drive currents as well as sharing the driver TFTs, and eliminates capacitor lines to provide storage capacitors to retain the gate electric potentials of the driver TFTs, the aperture ratio can be improved and consequently the visibility of the grating pattern at the borders between the pixels can be reduced to reduce the grainy look on the display panel.

In addition, since the electroluminescent display device according to the second embodiment is of the semi-passive drive type and uses the line-sequential drive, the signals for each row are provided all together and the signals are provided in common to the columns by the switch provided to each column to reduce variations in the brightness among the rows. The variations in the brightness among the columns are reduced by the compensation for the threshold voltages of the driver TFTs in the data line drive circuit that controls the amount of the electric current provided line-sequentially. The effects of suppressing the variations in the brightness among rows and columns result in the suppression of variations in the brightness of all the pixels over the panel to enable reducing the coarse look on the display panel.

Because various kinds of drive circuits such as the horizontal shift register, the data line drive circuit and the vertical shift register are formed on the single glass substrate together with the pixel region in which the electroluminescent devices are formed, there is no need to attach the external driver IC, making it possible to reduce the cost. In addition, there is no need to provide the cathode line isolation material to separate the cathode lines, which is required in the conventional passive drive type display device.

Also, because the electroluminescent display device according to the second embodiment adopts the line-sequential drive method used in an LCD and the like, in which the data line drive circuit provides the data lines with the drive currents all together for a predetermined period (one horizontal period, for example), the light-emitting period is made longer and thus a brighter display panel is made available compared with a conventional passive drive type display device that uses a dot-sequential drive method.

The electroluminescent display device according to the second embodiment of this invention is suitable for a small display device such as a display device for the EVF.

According to the data line drive circuit of the embodiments, the variations in the brightness on the display panel can be reduced to improve the quality of the display because the data line drive circuit outputs drive currents compensated for the threshold voltage of the driver transistors. Also, the light-emitting period of the organic EL devices can be extended by providing the first and second data line drive circuits and by outputting the drive currents alternately from the first and second data line drive circuits.

What is claimed is:

1. An electroluminescent display device comprising:
a plurality of data lines aligned in a first direction;
a plurality of cathode lines aligned in a second direction;
a plurality of electroluminescent devices, each of the electroluminescent devices being disposed at one of intersections of the data lines and the cathode lines;
a horizontal shift register that sequentially samples display signals;
a data line drive circuit that receives and retains the display signals sampled by the horizontal shift register and provides the data lines with drive currents in response to the display signals for a predetermined period;
a vertical shift register that sequentially selects the cathode lines and sets an electric potential of a selected cathode line so that drive currents flow through corresponding electroluminescent devices; and
a substrate on which the electroluminescent devices, the horizontal shift register, the data line drive circuit and the vertical shift register are formed.

2. The electroluminescent display device of claim 1, further comprising a layer of an isolation material disposed between two adjacent cathode lines.

3. The electroluminescent display device of claim 1, wherein the predetermined period is one horizontal period.

4. The electroluminescent display device of claim 1, wherein the data line drive circuit comprises a driver transistor that generates drive currents in response to the display signals and a threshold voltage compensation circuit that compensates for a threshold voltage of the driver transistor.

5. The electroluminescent display device of claim 1, wherein the electroluminescent device comprises an organic electroluminescent layer or an inorganic electroluminescent layer.

6. An electroluminescent display device comprising:
a plurality of data lines aligned in a first direction;
a plurality of gate lines aligned in a second direction;
a plurality of pixels defined by the data lines and the gate lines;
a pixel selection transistor disposed in each of the pixels, a gate of the pixel selection transistor being connected with a corresponding gate line and a drain of the pixel selection transistor being connected with a corresponding data line;
an electroluminescent device disposed in each of the pixels, the electroluminescent device being connected with a source of a corresponding pixel selection transistor;
a horizontal shift register that sequentially samples display signals;
a data line drive circuit that receives and retains the display signals sampled by the horizontal shift register and provides the data lines with drive currents in response to the display signals for a predetermined period;
a vertical shift register that outputs vertical scan signals to the gate lines; and
a substrate on which the pixel selection transistors, the electroluminescent devices, the horizontal shift register, the data line drive circuit and the vertical shift register are formed.

7. The electroluminescent display device of claim 6, wherein the predetermined period is one horizontal period.

8. The electroluminescent display device of claim 6, wherein the data line drive circuit comprises a driver transistor that generates drive currents in response to the display signals and a threshold voltage compensation circuit that compensates for a threshold voltage of the driver transistor.

9. The electroluminescent display device of claim 6, wherein the electroluminescent device comprises an organic electroluminescent layer or an inorganic electroluminescent layer.

10. A data line drive circuit that provides an electroluminescent device with a drive current through a data line, comprising:
a first data line drive circuit that comprises a first driver transistor, provides the data line with a first drive current during a first period and compensates the first drive current for a threshold voltage of the first driver transistor; and
a second data line drive circuit that comprises a second driver transistor, provides the data line with a second drive current during a second period and compensates the second drive current for a threshold voltage of the second driver transistor.

11. The data line drive circuit of claim 10, wherein the first data line drive circuit comprises;
a first transistor that receives a display signal in response to a first control signal,
a coupling capacitor comprising a first terminal and a second terminal, the display signal being applied to the first terminal through the first transistor,
a second transistor comprising a gate connected with the second terminal of the coupling capacitor, the second transistor providing the electroluminescent device with the first drive current corresponding to the display signal,
a third transistor that short-circuits the gate and a drain of the second transistor in response to the first control signal,
a fourth transistor that sets an electric potential of the first terminal of the coupling capacitor at a reference electric potential in response to a second control signal; and
a fifth transistor that is connected between the drain of the second transistor and a ground and discharges electric charges accumulated at the gate of the second transistor to the ground in response to a third control signal.

12. The data line drive circuit of claim 11, wherein the second data line drive circuit comprises;
another first transistor that receives a display signal in response to a fourth control signal,
another coupling capacitor comprising a first terminal and a second terminal, the display signal being applied to the first terminal through the another first transistor,
another second transistor comprising a gate connected with the second terminal of the another coupling capacitor, the another second transistor providing the electroluminescent device with the second drive current corresponding to the display signal,
another third transistor that short-circuits the gate and a drain of the another second transistor in response to the fourth control signal
another fourth transistor that sets an electric potential of the first terminal of the another coupling capacitor at a reference electric potential in response to a fifth control signal; and
another fifth transistor that is connected between the drain of the another second transistor and a ground and discharges electric charges accumulated at the gate of the another second transistor to the ground in response to a sixth control signal.

13. The data line drive circuit of claim 12, wherein the fourth, fifth and sixth control signals are shifted by one horizontal period from the first, second and third control signals, respectively.

14. The data line drive circuit of claim 10, 11, 12 or 13, wherein the electroluminescent device comprises an organic electroluminescent layer or an inorganic electroluminescent layer.
